(19) United States
(12) Patent Application Publication
(10) Pub. No.: US 2026/0044637 A1
(43) Pub. Date: Feb. 12, 2026

(54) MANAGING FLOW OF INFORMATION WITHIN A VENUE DATA PROCESSING ENVIRONMENT

(71) Applicant: Sphere Entertainment Group, LLC, New York, NY (US)

(72) Inventors: Yuan-Yi FAN, New York, NY (US); Neil WAKEFIELD, New York, NY (US)

(73) Assignee: Sphere Entertainment Group, LLC, New York, NY (US)

(21) Appl. No.: 18/795,464

(22) Filed: Aug. 6, 2024

(51) Int. Cl. G06F 30/13

(52) U.S. Cl. CPC G06F 30/13

(57) ABSTRACT

Systems, methods, and apparatuses advantageously provide timely, reliable, and/or consistent flow of information, for example, audio, video, and/or data, among others, within a venue data processing environment. These systems, methods, and apparatuses can generate a venue configuration file that specifies one or more characteristics, parameters, and/or attributes of the venue. These systems, methods, and apparatuses can standardize the venue configuration file to beneficially ensure consistency, reliability, and efficiency. These systems, methods, and apparatuses can process the information in accordance with one or more characteristics, parameters, and/or attributes. As part of this processing, these systems, methods, and apparatuses can load the venue configuration file to subsequently read the one or more characteristics, parameters, and/or attributes of the venue that are stored in the venue configuration file.

### BACKGROUND

Effective audio and video production are crucial for ensuring a successful event in a venue, significantly impacting the audience's experience. Audio and video production beneficially utilize venue data that is crucial for designing and planning the event. Having detailed venue data allows audio engineers and production teams to design and plan the event to the specific characteristics and needs of the venue.

### BRIEF DESCRIPTION OF THE DRAWINGS

The present disclosure is described with reference to the accompanying drawings. In the drawings, like reference numbers indicate identical or functionally similar elements. Additionally, the left most digit(s) of a reference number identifies the drawing in which the reference number first appears. In the accompanying drawings:

FIG. 1 graphically illustrates a simplified block diagram of an exemplary venue data processing environment according to some exemplary embodiments of the present disclosure;

FIG. 2 graphically illustrates a simplified block diagram of an audio pipeline architecture that can be implemented within the exemplary venue data processing environment according to some exemplary embodiments of the present disclosure;

FIG. 3A through FIG. 3D illustrate simplified block diagrams for exemplary configurations and/or arrangements for software tools that can be implemented within the exemplary venue data processing environment according to some exemplary embodiments of the present disclosure;

FIG. 4 illustrates an exemplary operational control flow for the exemplary venue data processing environment in accordance with some exemplary embodiments of the present disclosure; and

FIG. 5 illustrates a simplified block diagram of an exemplary computer system that can be implemented within the exemplary venue data processing environment according to some exemplary embodiments of the present disclosure.

The present disclosure will now be described with reference to the accompanying drawings.

### DETAILED DESCRIPTION

The following disclosure provides many different embodiments, or examples, for implementing different features of the provided subject matter. Specific examples of components and arrangements are described herein to simplify the present disclosure. These are, of course, merely examples and are not intended to be limiting. Aspects of the present disclosure are best understood from the following detailed description when read with the accompanying figures. The present disclosure may repeat reference numerals and/or letters in the various examples. This repetition does not in itself dictate a relationship between the various embodiments and/or configurations discussed. It is noted that, in accordance with the standard practice in the industry, features are not drawn to scale. In fact, the dimensions of the features may be arbitrarily increased or reduced for clarity of discussion. The following disclosure may include the terms “about” or “substantially” to indicate the value of a given quantity can vary based on a particular technology. Based on the technology, the term “about” or “substantially” can indicate a value of a given quantity that varies within, for example, 1-15% of the value (e.g., ±1%, ±2%, ±5%, ±10%, or ±15% of the value).

### OVERVIEW

Systems, methods, and apparatuses advantageously provide timely, reliable, and/or consistent flow of information, for example, audio, video, and/or data, among others, within a venue data processing environment. These systems, methods, and apparatuses can generate a venue configuration file that specifies one or more characteristics, parameters, and/or attributes of the venue. These systems, methods, and apparatuses can standardize the venue configuration file to beneficially ensure consistency, reliability, and efficiency. These systems, methods, and apparatuses can process the information in accordance with one or more characteristics, parameters, and/or attributes. As part of this processing, these systems, methods, and apparatuses can load the venue configuration file to subsequently read the one or more characteristics, parameters, and/or attributes of the venue that are stored in the venue configuration file.

### Exemplary Venue Data Processing Environment

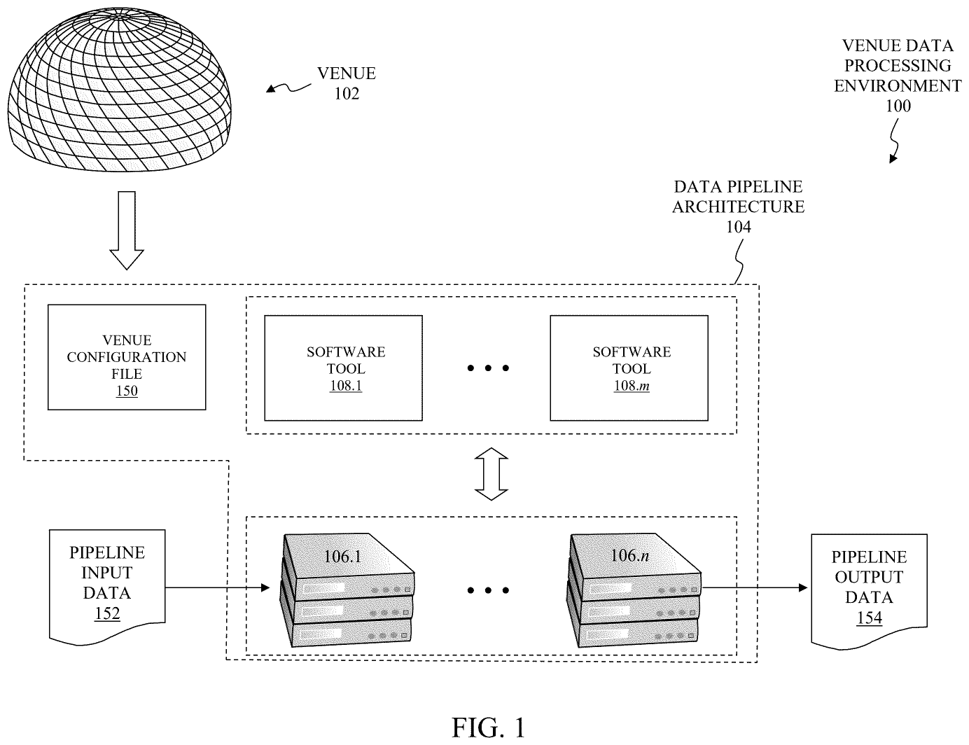

FIG. 1 graphically illustrates a simplified block diagram of an exemplary venue data processing environment according to some exemplary embodiments of the present disclosure. In the exemplary embodiment illustrated in FIG. 1, a venue data processing environment 100 includes a venue 102 for hosting an event. For example, the venue 102 can represent a music venue, for example, a music theater, a music club, and/or a concert hall, a sporting venue, for example, an arena, a convention center, and/or a stadium, and/or any other suitable venue that will be apparent to those skilled in the relevant art(s) without departing the spirit and scope of the present disclosure. The event can represent a musical event, a theatrical event, a sporting event, a motion picture, and/or any other suitable event that will be apparent to those skilled in the relevant art(s) without departing the spirit and scope of the present disclosure. As illustrated in FIG. 1, the venue data processing environment 100 further includes a data pipeline architecture 104.

In the exemplary embodiment illustrated in FIG. 1, the venue 102 can playback information, for example, audio, video, and/or data, among others, that is associated with the event. In some embodiments, the venue 102 can represent a three-dimensional structure, for example, a spherical structure, a spherical-like structure, a hemispherical structure, also referred to as a hemispherical dome, or a hemispherical-like structure, among others. In some embodiments, the venue 102 can include one or more visual displays, often referred to as a media plane, that are spread across the interior of the venue 102. In these embodiments, the media plane can be implemented be configured and arranged to be a three-dimensional media plane that is spread across the interior of the venue 102. Alternatively, or in addition to, the one or more visual displays can be spread across the exterior of the venue 102. For example, the three-dimensional media plane can include a 19,000 by 13,500 LED visual display that wraps around the interior of the venue 102 to form an approximate 160,000 square foot three-dimensional media plane visual display. As another example, the three-dimensional media plane can include approximately 1.23 million puck-shaped LEDs that wrap around the exterior of the venue 102 to form an approximate 580,000 square foot three-dimensional media plane visual display. Alternatively, or in addition to, the venue 102 can include one or more loudspeakers. In some embodiments, the one or more loudspeakers can include a proscenium array loudspeaker system that is situated at, or near, a proscenium of the venue 102, one or more effects extensions array loudspeaker systems that are situated at, or near, the proscenium array real-world loudspeaker system, and/or one or more environmental array loudspeaker systems that are situated throughout the venue 102. In some embodiments, the proscenium array loudspeaker system, the one or more effects extensions array loudspeaker systems, and/or the one or more environmental array loudspeaker systems can include one or more one or more real-world loudspeakers that can include one or more super tweeters, one or more tweeters, one or more mid-range speakers, one or more woofers, one or more subwoofers, and/or one or more full-range speakers to provide some examples.

In the exemplary embodiment illustrated in FIG. 1, the data pipeline architecture 104 manages flow of information, for example, audio, video, and/or data, among others, within the venue data processing environment 100. In some embodiments, the data pipeline architecture 104 advantageously provides timely, reliable, and/or consistent flow of the information within the venue data processing environment 100. Although the data pipeline architecture 104 is illustrated in FIG. 1 as being within the venue data processing environment 100 in FIG. 1, those skilled in the relevant art(s) will recognize the data pipeline architecture 104 can alternatively, or additionally, be implemented as a standalone electrical, mechanical, and/or electro-mechanical device without departing from the spirit and scope of the present disclosure. In the exemplary embodiment illustrated in FIG. 1, the data pipeline architecture 104 can be implemented using one or more firmware, software, routines, instructions, or the like, referred to as software tools 108.1 through 108.n for simplicity, executing one or more computing devices 106.1 through 106.n. Although the software tools 108.1 through 108.n may be described herein as performing certain actions, it should be appreciated that such descriptions are merely for convenience and that these actions result from the one or more computing devices 106.1 through 106.n executing the software tools 108.1 through 108.n. In some embodiments, the one or more computing devices 106.1 through 106.n can include a single computing devices executing the software tools 108.1 through 108.n. Alternatively, or in addition to, multiple computing devices from among the one or more computing devices 106.1 through 106.n can functionally cooperate to execute the software tools 108.1 through 108.n. In the exemplary embodiment illustrated in FIG. 1, the data pipeline architecture 104 can generate a venue configuration file 150 that specifies one or more characteristics, parameters, and/or attributes of the venue 102. As described herein, the data pipeline architecture 104 can standardize the venue configuration file 150 to beneficially ensure consistency, reliability, and efficiency. In some embodiments, the data pipeline architecture 104 can use a common format for the venue configuration file 150. In these embodiments, the common format can facilitate the seamless integration among the software tools 108.1 through 108.n. Alternatively, or in addition, the data pipeline architecture 104 can define and/or enforce a common schema to conform the venue configuration file 150 to expected structures and/or types, among others. In some embodiments, the common schema can outline the organization, format, and/or constraints, among others, of the venue configuration file 150. In these embodiments, the common schema can specify how the venue configuration file 150 is stored, organized, and accessed, and can include information about tables, fields, data types, relationships and/or constraints, among others. In some embodiments, the data pipeline architecture 104 provides the venue configuration file 150 to the software tools 108.1 through 108.n for storage and/or retrieval. In some embodiments, the common format and/or the common schema beneficially allows each of the software tools 108.1 through 108.n to read the one or more characteristics, parameters, and/or attributes of the venue 102 from the venue configuration file 150 without further modification.

As illustrated in FIG. 1, the data pipeline architecture 104 can process pipeline input data 152 to provide pipeline output data 154. In some embodiments, the pipeline input data 152 and/or the pipeline output data 154 can include audio, video, and/or data, among others, to be processed by the data pipeline architecture 104. In these embodiments, the audio, video, and/or data can include structured data that is organized in a fixed format, semi-structured data, unstructured data, streaming data, batch data, transactional data, and/or external data, among others. In some embodiments, the software tools 108.1 through 108.n can process the pipeline input data 152 in accordance with one or more characteristics, parameters, and/or attributes of the venue 102 to provide the pipeline output data 154. Generally, the one or more software tools 108.1 through 108.n implement one or more firmware, software applications, routines, instructions, etc. for processing information, for example, audio, video, and/or data, among others. In some embodiments, the one or more software tools 108.1 through 108.n can range from simple software tools that perform a single function, method, procedure, routine, algorithm, action, process, operation, or the like to complex software tools that support a wide array of functions, methods, procedures, routines, algorithms, actions, processes, operations, or the like. In these embodiments, these functions, methods, procedures, routines, algorithms, actions, processes, operations, or the like can include integration, migration, transformation, monitoring, visualization, and/or analysis of the pipeline input data 152 and/or pipeline output data 154 as well as other information, for example, audio, video, and/or data, among others. As part of this processing, the software tools 108.1 through 108.n can read the pipeline input data 152. In some embodiments, the software tools 108.1 through 108.n can perform a batch reading of the pipeline input data 152 and/or a streaming reading of the pipeline input data 152. As part of this processing, the software tools 108.1 through 108.n can load the venue configuration file 150 to subsequently read the one or more characteristics, parameters, and/or attributes of the venue 102 that are stored in the venue configuration file 150. As part of this processing, the software tools 108.1 through 108.n can process the pipeline input data 152 read into the data pipeline architecture 104 in accordance with the one or more characteristics, parameters, and/or attributes of the venue 102 read from the venue configuration file 150 to provide the pipeline output data 154.

### Exemplary Audio Pipeline Architecture

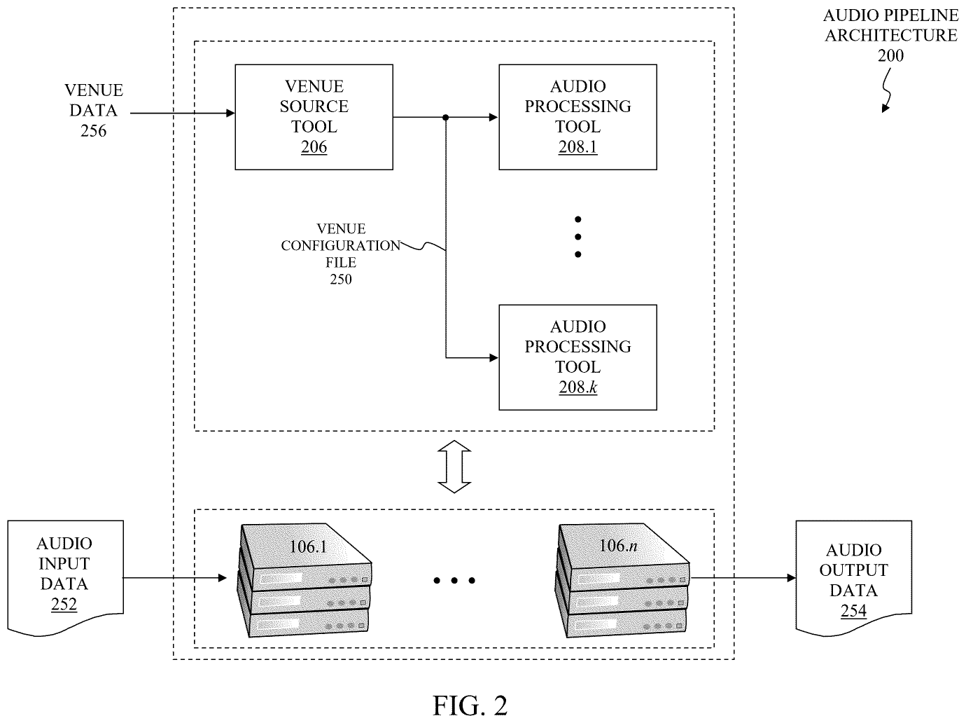

FIG. 2 graphically illustrates a simplified block diagram of an audio pipeline architecture that can be implemented within the exemplary venue data processing environment according to some exemplary embodiments of the present disclosure. In the exemplary embodiment illustrated in FIG. 2, an audio pipeline architecture 200 advantageously provides timely, reliable, and/or consistent flow of audio within a venue audio processing environment, such as the venue data processing environment 100. As illustrated in FIG. 2, the audio pipeline architecture 200 can be implemented using one or more firmware, software, routines, instructions, or the like executing the one or more computing devices 106.1 through 106.n. In the exemplary embodiment illustrated in FIG. 2, the one or more firmware, software, routines, instructions, or the like can include a venue source tool 206 and/or one or more audio processing tools 208.1 through 208.k. Although the venue source tool 206 and/or the one or more audio processing tools 208.1 through 208.k may be described herein as performing certain actions, it should be appreciated that such descriptions are merely for convenience and that these actions result from the one or more computing devices 106.1 through 106.n executing the venue source tool 206 and/or the one or more audio processing tools 208.1 through 208.k. In some embodiments, the audio pipeline architecture 200 can represent an exemplary embodiment of the data pipeline architecture 104.

In the exemplary embodiment illustrated in FIG. 2, the venue source tool 206 can generate the venue configuration file 250 that specifies the one or more characteristics, parameters, and/or attributes of a venue, such as the venue 102. In some embodiments, the one or more characteristics, parameters, and/or attributes of the venue can be related to the venue dimensions and layout, acoustic characteristics, seating layout, stage dimensions and position, loudspeaker locations, microphone placement zones, power outlets and distribution, sound system specifications, cable routes and trays, audience areas, loading and access points, and/or environmental noise sources, among others. In these embodiments, the one or more characteristics, parameters, and/or attributes of the venue can include, but are not limited to, channel order, channel grouping, channel location, channel, label, seat section location, target seat section, reverb send level, reverb delay, and/or impulse response information for seat section location, among others. As illustrated in FIG. 2, the venue source tool 206 can access venue data 256 that is associated with the venue. In some embodiments, the venue source tool 206 can receive the venue data 256 from the venue. In these embodiments, the venue data 256 can be in a non-standard format and/or a non-standard schema that does not confirm to the common format and/or the common schema, respectively, described herein. For example, the venue data 256 can be formatted in accordance with a propriety format or a propriety schema that is unique to the venue and which can differ between venues. In some embodiments, the venue data 256 can be related to the capacity and/or layout of the venue, for example, total seating capacity, layout of seating areas, dimensions and/or configuration of the stage, location and/or size of entry and/or exit points; the acoustics of the venue, for example, acoustic properties of the venue, audio system specifications, capabilities, and locations, and/or the visuals of the venue, for example, projection capabilities, sightlines from different seating areas, and/or availably and/or location of video displays, among others. In the exemplary embodiment illustrated in FIG. 2, the venue source tool 206 transforms, for example, compiles, the venue data 256 to generate the venue configuration file 250 having the common format and/or the common schema describe herein. As illustrated in FIG. 2, the venue source tool 206 can provide the venue configuration file 250 to the one or more audio processing tools 208.1 through 208.k. In some embodiments, the venue configuration file 250 can represent an exemplary embodiment of the venue configuration file 150.

In the exemplary embodiment illustrated in FIG. 2, the one or more audio processing tools 208.1 through 208.k can process audio input data 252 to provide audio output data 254. In some embodiments, the audio input data 252 and/or the audio output data 254 can include audio and/or data that is associated with an event that can be configured and arranged to be structured data that is organized in a fixed format, semi-structured data, unstructured data, streaming data, and/or batch data, among others. In some embodiments, one or more of the one or more audio processing tools 208.1 through 208.k can process the audio input data 252 in accordance with one or more characteristics, parameters, and/or attributes of the venue to provide the audio output data 254. As part of this processing, the one or more audio processing tools 208.1 through 208.k can read the audio input data 252. In some embodiments, the one or more audio processing tools 208.1 through 208.k can perform a batch reading of the audio input data 252 and/or a streaming reading of the audio input data 252. As part of this processing, the one or more audio processing tools 208.1 through 208.k can load the venue configuration file 250 to subsequently read the one or more characteristics, parameters, and/or attributes of the venue that are stored in the venue configuration file 250. As part of this processing, the one or more audio processing tools 208.1 through 208.k can process the audio input data 252 read into the data pipeline architecture 104 in accordance with the one or more characteristics, parameters, and/or attributes of the venue read from the venue configuration file 250 to provide the audio output data 254.

In some embodiments, the one or more audio processing tools 208.1 through 208.k can include a panner, a router/panner, an audio visualizer, an auralizer, a channel monitor, and/or a control surface, among others. In these embodiments, the panner enables panning of the audio input data 252 by reading channel order, label, channel location, and/or channel grouping, among others, as the one or more characteristics, parameters, and/or attributes from the venue configuration file 250. In these embodiments, the router/panner enables spatializing of the audio input data 252 by reading channel order, label, channel location, and/or channel grouping, among others, as the one or more characteristics, parameters, and/or attributes from the venue configuration file 250. In these embodiments, the audio visualizer enables visualizing custom channel layers onto various monitoring facilities by reading channel order, seat section location, and/or target seat section, among others, as the one or more characteristics, parameters, and/or attributes from the venue configuration file 250. In these embodiments, the auralizer enables auralization for various monitoring venues, for various listener locations, and/or for various room modeling, by reading channel order, seat section location, target seat section, and/or impulse response information for seat section location, among others, as the one or more characteristics, parameters, and/or attributes from the venue configuration file 250. In these embodiments, the channel monitor enables visualizing of monitoring locations by reading seat section location and/or target seat section, among others, as the one or more characteristics, parameters, and/or attributes from the venue configuration file 250. In these embodiments, the control surface enables panning of the audio input data 252 by reading channel order, label, channel location, and/or channel grouping, among others, as the one or more characteristics, parameters, and/or attributes from the venue configuration file 250; enables visualizing channel activation status, beam coverage zone, and channel layers by reading channel location, channel grouping, and/or target seat section data, among others, as the one or more characteristics, parameters, and/or attributes from the venue configuration file 250; and/or enables visualizing of monitoring locations by reading seat section location and/or target seat section, among others, as the one or more characteristics, parameters, and/or attributes from the venue configuration file 250.

Exemplary Configurations and/or Arrangements for Software Tools that can be Implemented within the Exemplary Venue Data Processing Environment

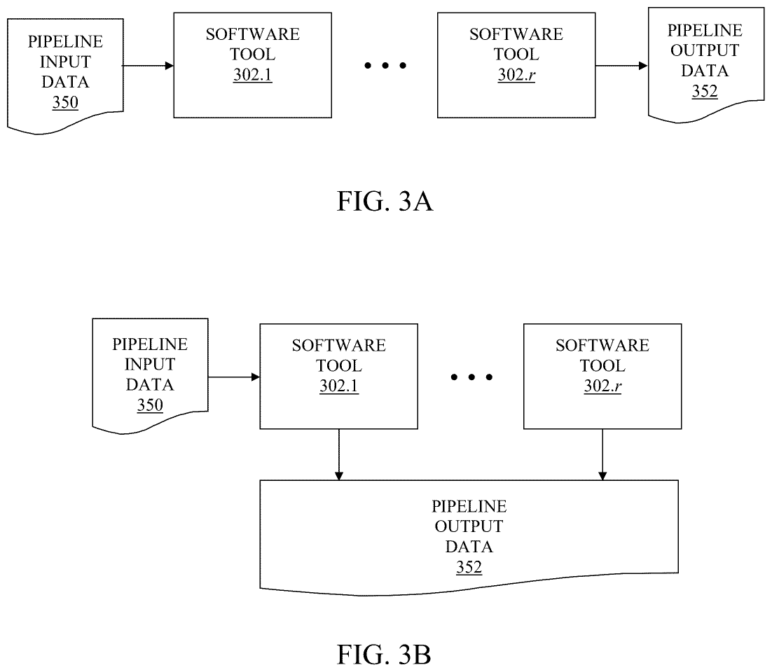

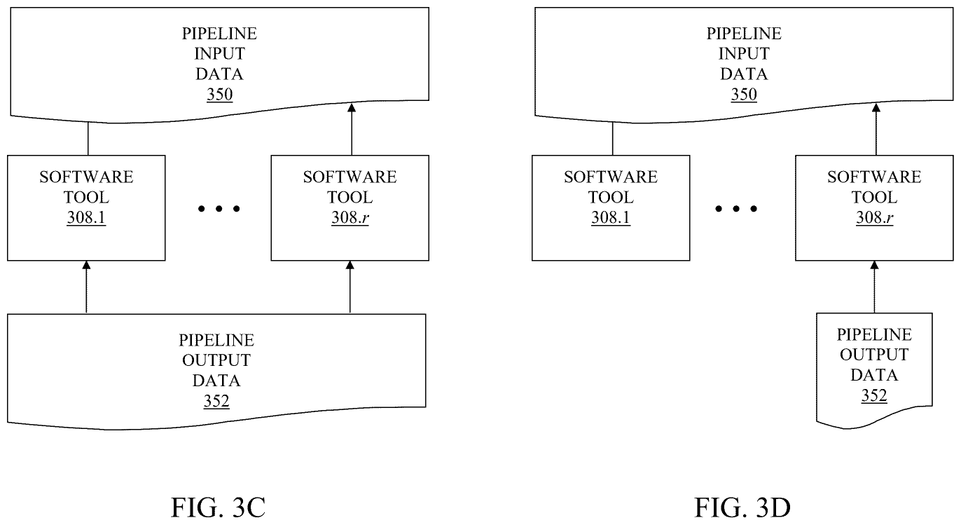

FIG. 3A through FIG. 3D illustrate simplified block diagrams for exemplary configurations and/or arrangements for software tools that can be implemented within the exemplary venue data processing environment according to some exemplary embodiments of the present disclosure. As illustrated in FIG. 3A through FIG. 3D, software tools 302.1 through 302.r can process pipeline input data 350 to provide pipeline output data 352. In some embodiments, the pipeline input data 350 and/or the pipeline output data 352 can include audio, video, and/or data, among others, to be processed by the software tools 302.1 through 302.r. In some embodiments, the pipeline input data 350 and the pipeline output data 352 can represent exemplary embodiments of the pipeline input data 152 and the pipeline output data 154, respectively, and/or the audio input data 252 and the audio output data 254, respectively. Although the software tools 302.1 through 302.r may be described herein as performing certain actions, it should be appreciated that such descriptions are merely for convenience and that these actions result from the one or more computing devices 106.1 through 106.n executing the software tools 302.1 through 302.r. In some embodiments, the software tools 302.1 through 302.r can represent an exemplary embodiment of the software tools 108.1 through 108.n, the one or more audio processing tools 208.1 through 208.k, one or more subsets thereof, and/or combinations of the one or more subsets thereof. Although the discussion of FIG. 3A through FIG. 3D to follow is to describe exemplary configurations and/or arrangements for the software tools 302.1 through 302.r, those skilled in the relevant art(s) will recognize that one or more features, structures, and/or characteristics of any of these configurations and/or arrangements, combinations, or subcombinations, of any of these configurations and/or arrangements, and/or permutations, or subpermutations, of any of these configurations and/or arrangements may be included, independently or in any combination, with other features, structures, or characteristics of any of these configurations and/or arrangements, combinations, or subcombinations, of any of these configurations and/or arrangements, and/or permutations, or subpermutations, of any of these configurations and/or arrangements to form other configurations and/or arrangements for the software tools 302.1 through 302.r whether or not explicitly described without departing from the spirit and scope of the present disclosure.

As illustrated in FIG. 3A through FIG. 3D, the software tools 302.1 through 302.r can process the pipeline input data 350 to provide the pipeline output data 352. As described herein, this processing can include integration, migration, transformation, monitoring, visualization, and/or analysis of the pipeline input data 350 and/or the pipeline output data 352, among others. In some embodiments, the software tools 302.1 through 302.r can process the pipeline input data 350 in accordance with one or more characteristics, parameters, and/or attributes of the venue to provide the pipeline output data 352. As part of this processing, the software tools 302.1 through 302.r can load a venue configuration file, such as, the venue configuration file 150 and/or the venue configuration file 250 to provide some examples, to subsequently read the one or more characteristics, parameters, and/or attributes of a venue, such as the venue 102 to provide an example, that are stored in the venue configuration file.

In the exemplary embodiment illustrated in FIG. 3A, the software tools 302.1 through 302.r can process the pipeline input data 350 in accordance with the one or more characteristics, parameters, and/or attributes of the venue read from the venue configuration file to provide the pipeline output data 352 as part of this processing. As illustrated in FIG. 3A, one of the one or more software tools 302.1 through 302.r, for example, the software tool 302.1, can read the pipeline input data 350. The software tool 302.1 can thereafter process the pipeline input data 350 in accordance with the one or more characteristics, parameters, and/or attributes of the venue. Thereafter, another one of the one or more software tools 302.1 through 302.r, for example, the software tool 302.r, can access information, for example, audio, video, and/or data, generated by the software tool 302.1 while processing the pipeline input data 350. The software tool 302.r can subsequently process the information generated by the software tool 302.1 in accordance with the one or more characteristics, parameters, and/or attributes of the venue to provide the pipeline output data 352.

In the exemplary embodiment illustrated in FIG. 3B, the software tools 302.1 through 302.r can process the pipeline input data 350 in accordance with the one or more characteristics, parameters, and/or attributes of the venue read from the venue configuration file to provide the pipeline output data 352 as part of this processing. As illustrated in FIG. 3B, one of the one or more software tools 302.1 through 302.r, for example, the software tool 302.1, can read the pipeline input data 350. The software tool 302.1 can thereafter process the pipeline input data 350 in accordance with the one or more characteristics, parameters, and/or attributes of the venue to provide the pipeline output data 352. Thereafter, another one of the one or more software tools 302.1 through 302.r, for example, the software tool 302.r, can access information, for example, audio, video, and/or data, generated by the software tool 302.1 while processing the pipeline input data 350. The software tool 302.r can subsequently process the information generated by the software tool 302.1 in accordance with the one or more characteristics, parameters, and/or attributes of the venue to provide the pipeline output data 352.

In the exemplary embodiment illustrated in FIG. 3C, the software tools 302.1 through 302.r can process the pipeline input data 350 in accordance with the one or more characteristics, parameters, and/or attributes of the venue read from the venue configuration file to provide the pipeline output data 352 as part of this processing. As illustrated in FIG. 3C, one of the one or more software tools 302.1 through 302.r, for example, the software tool 302.1, can read the pipeline input data 350. The software tool 302.1 can thereafter process the pipeline input data 350 in accordance with the one or more characteristics, parameters, and/or attributes of the venue to provide the pipeline output data 352. Another one of the one or more software tools 302.1 through 302.r, for example, the software tool 302.r, can read the pipeline input data 350. The software tool 302.r can subsequently process the pipeline input data 350 in accordance with the one or more characteristics, parameters, and/or attributes of the venue to provide the pipeline output data 352.

In the exemplary embodiment illustrated in FIG. 3D, the software tools 302.1 through 302.r can process the pipeline input data 350 in accordance with the one or more characteristics, parameters, and/or attributes of the venue read from the venue configuration file to provide the pipeline output data 352 as part of this processing. As illustrated in FIG. 3D, one of the one or more software tools 302.1 through 302.r, for example, the software tool 302.1, can read the pipeline input data 350. The software tool 302.1 can thereafter process the pipeline input data 350 in accordance with the one or more characteristics, parameters, and/or attributes of the venue. Another one of the one or more software tools 302.1 through 302.r, for example, the software tool 302.r, can read the pipeline input data 350. The software tool 302.r can subsequently process the pipeline input data 350 in accordance with the one or more characteristics, parameters, and/or attributes of the venue to provide the pipeline output data 352.

### Exemplary Operational Control Flows for the Exemplary Venue Data Processing Environment

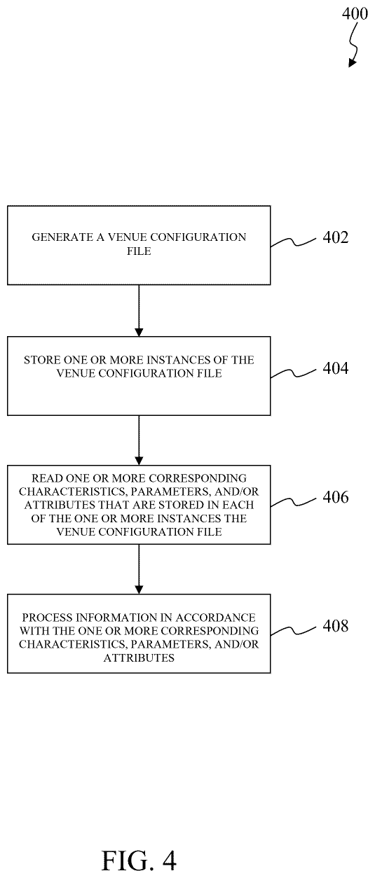

FIG. 4 illustrates an exemplary operational control flow for the exemplary venue data processing environment in accordance with some exemplary embodiments of the present disclosure. The following discussion is to describe an exemplary operational control flow 400 for advantageously providing timely, reliable, and/or consistent flow of information, such as audio, video, and/or data, among others, within a venue audio processing environment, such as the venue data processing environment 100. The present disclosure is not limited to these exemplary operational control flows. In some embodiments, the operational control flow 400 can be performed by the one or more of the one or more computing devices 106.1 through 106.n described herein.

At operation 402, the operational control flow 400 generates a venue configuration file, such as the venue configuration file 150 and/or the venue configuration file 250 to provide some examples. In some embodiments, the venue configuration file can specify the one or more characteristics, parameters, and/or attributes of a venue, such as the venue 102. In these embodiments, the one or more characteristics, parameters, and/or attributes of the one or more characteristics, parameters, and/or attributes of the venue can be related to the venue dimensions and layout, acoustic characteristics, seating layout, stage dimensions and position, loudspeaker locations, microphone placement zones, power outlets and distribution, sound system specifications, cable routes and trays, audience areas, loading and access points, and/or environmental noise sources, among others. Alternatively, or in addition to, the one or more characteristics, parameters, and/or attributes of the one or more characteristics, parameters, and/or attributes of the venue can be related to the venue dimensions and layout, seating layout, stage dimensions and position, lightning grid, screen and projector locations, camera placement zones, power outlets and distribution, control room setup, cable routes and trays, backdrop and set design, access and exits, ambient light sources, existing audio-visual equipment, and/or network connectivity, among others. In some embodiments, the operational control flow 400 can access venue data, such as the venue data 256 to provide an example, that is associated with the venue. In these embodiments, the operational control flow 400 transforms, for example, compiles, the venue data in accordance with the common format and/or the common schema for the venue configuration file 250 in a substantially similar manner as the data pipeline architecture 104 to generate the venue configuration file.

At operation 404, the operational control flow 400 stores one or more instances of the venue configuration file from operation 402. In some embodiments, the operational control flow 400 provides the venue configuration file from operation 402 to each of the one or more software tools for storage and/or retrieval. In these embodiments, each of the one or more software tools stores its own venue configuration file from operation 402 for retrieval. In some embodiments, the operational control flow 400 can provide the venue configuration file from operation 402 to each of the one or more software tools in accordance with one or more communications protocols can, such as Hypertext Transfer Protocol (HTTP), Transmission Control Protocol/Internet Protocol (TCP/IP), Real-Time Transport Protocol (RTP), Real Time Streaming Protocol (RTSP), Internetwork Packet Exchange (IPX), and/or User Datagram Protocol (UDP), among others to provide some examples.

At operation 406, the operational control flow 400 reads one or more corresponding characteristics, parameters, and/or attributes that are stored in each of the one or more instances the venue configuration file stored in operation 404. In some embodiments, the operational control flow 400 loads the one or more instances the venue configuration file stored in operation 404. In these embodiments, the operational control flow 400 subsequently reads the one or more corresponding characteristics, parameters, and/or attributes that are stored in each of the one or more instances the venue configuration file stored in operation 404.

At operation 408, the operational control flow 400 processes information, for example, audio, video, and/or data, among others, in accordance with the one or more corresponding characteristics, parameters, and/or attributes read from operation 406. Generally, the operational control flow 400 can implement one or more firmware, software applications, routines, instructions, etc. for processing information, for example, audio, video, and/or data, among others. In some embodiments, the one or more firmware, software applications, routines, instructions, etc. can range from simple functions, methods, procedures, routines, algorithms, actions, processes, operations, or the like to complex functions, methods, procedures, routines, algorithms, actions, processes, operations, or the like. In these embodiments, these functions, methods, procedures, routines, algorithms, actions, processes, operations, or the like can include integration, migration, transformation, monitoring, visualization, and/or analysis of the information, for example, audio, video, and/or data, among others. As part of this processing, the operational control flow 400 can read the information, for example, audio, video, and/or data, among others. As part of this processing, the operational control flow 400 can process the information, for example, audio, video, and/or data, among others, in accordance with the one or more corresponding characteristics, parameters, and/or attributes from operation 406.

Exemplary Computer System that can be Implemented within the Exemplary Venue Data Processing Environment

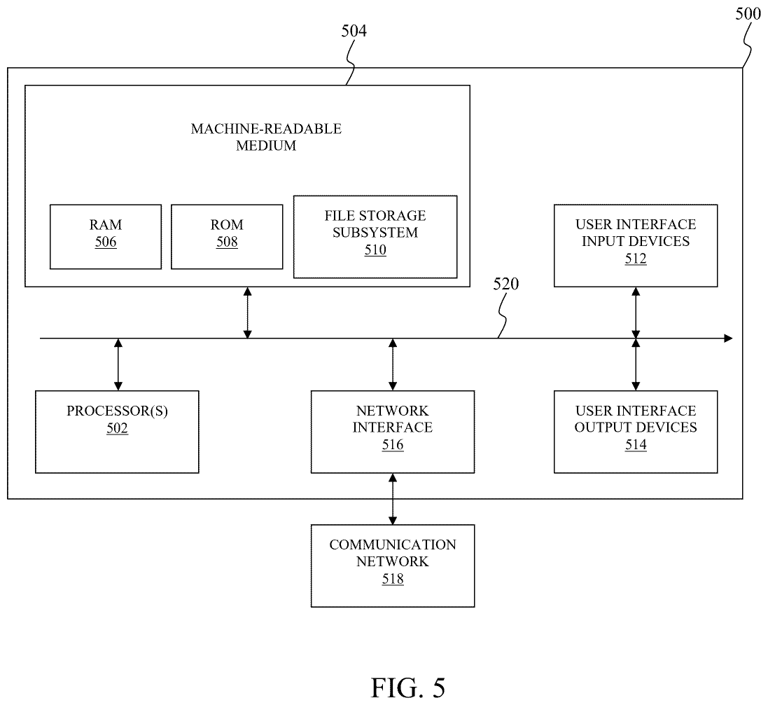

FIG. 5 illustrates a simplified block diagram of an exemplary computer system that can be implemented within the exemplary venue data processing environment according to some exemplary embodiments of the present disclosure. The discussion of FIG. 5 to follow is to describe a computer system 500 that can be used to implement one or more of the one or more computing devices 106.1 through 106.n described herein.

In the exemplary embodiment illustrated in FIG. 5, the computer system 500 includes one or more processors 502. In some embodiments, the one or more processors 502 can include, or can be, any of a microprocessor, graphics processing unit, or digital signal processor, and their electronic processing equivalents, such as an Application Specific Integrated Circuit (“ASIC”) or Field Programmable Gate Array (“FPGA”). As used herein, the term “processor” signifies a tangible data and information processing device that physically transforms data and information, typically using a sequence transformation (also referred to as “operations”). Data and information can be physically represented by an electrical, magnetic, optical, or acoustical signal that is capable of being stored, accessed, transferred, combined, compared, or otherwise manipulated by the processor. The term “processor” can signify a singular processor and multi-core systems or multi-processor arrays, including graphic processing units, digital signal processors, digital processors, or combinations of these elements. The processor can be electronic, for example, comprising digital logic circuitry (for example, binary logic), or analog (for example, an operational amplifier). The processor may also operate to support performance of the relevant operations in a “cloud computing” environment or as a “software as a service” (SaaS). For example, at least some of the operations may be performed by a group of processors available at a distributed or remote system, these processors accessible via a communications network (e.g., the Internet) and via one or more software interfaces (e.g., an application program interface (API).) In some embodiments, the computer system 500 can include an operating system, such as Microsoft's Windows, Sun Microsystems's Solaris, Apple Computer's MacOs, Linux or UNIX. In some embodiments, the computer system 500 can also include a Basic Input/Output System (BIOS) and processor firmware. The operating system, BIOS and firmware are used by the one or more processors 502 to control subsystems and interfaces coupled to the one or more processors 502. In some embodiments, the one or more processors 502 can include the Pentium and Itanium from Intel, the Opteron and Athlon from Advanced Micro Devices, and the ARM processor from ARM Holdings.

As illustrated in FIG. 5, the computer system 500 can include a machine-readable medium 504. In some embodiments, the machine-readable medium 504 can further include a main random-access memory (“RAM”) 506, a read only memory (“ROM”) 508, and/or a file storage subsystem 510. The RAM 506 can store instructions and data during program execution and the ROM 508 can store fixed instructions. The file storage subsystem 510 provides persistent storage for program and data files, and may include a hard disk drive, a floppy disk drive along with associated removable media, a CD-ROM drive, an optical drive, a flash memory, or a removable media cartridge.

The computer system 500 can further include user interface input devices 512 and user interface output devices 514. The user interface input devices 512 can include an alphanumeric keyboard, a keypad, pointing devices such as a mouse, trackball, touchpad, stylus, or graphics tablet, a scanner, a touchscreen incorporated into the display, audio input devices such as voice recognition systems or microphones, eye-gaze recognition, brainwave pattern recognition, and other types of input devices to provide some examples. The user interface input devices 512 can be connected by wire or wirelessly to the computer system 500. Generally, the user interface input devices 512 are intended to include all possible types of devices and ways to input information into the computer system 500. The user interface input devices 512 typically allow a user to identify objects, icons, text, and the like that appear on some types of user interface output devices, for example, a display subsystem. The user interface output devices 514 may include a display subsystem, a printer, a fax machine, or non-visual displays such as audio output devices. The display subsystem may include a cathode ray tube (CRT), a flat-panel device such as a liquid crystal display (LCD), a projection device, or some other device for creating a visible image such as a virtual reality system. The display subsystem may also provide non-visual display such as via audio output or tactile output (e.g., vibrations) devices. Generally, the user interface output devices 514 are intended to include all possible types of devices and ways to output information from the computer system 500.

The computer system 500 can further include a network interface 516 to provide an interface to outside networks, including an interface to a communication network 518, and is coupled via the communication network 518 to corresponding interface devices in other computer systems or machines. The communication network 518 may comprise many interconnected computer systems, machines, and communication links. These communication links may be wired links, optical links, wireless links, or any other devices for communication of information. The communication network 518 can be any suitable computer network, for example a wide area network such as the Internet, and/or a local area network such as Ethernet. The communication network 518 can be wired and/or wireless, and the communication network can use encryption and decryption methods, such as is available with a virtual private network. The communication network uses one or more communications interfaces, which can receive data from, and transmit data to, other systems. Embodiments of communications interfaces typically include an Ethernet card, a modem (e.g., telephone, satellite, cable, or ISDN), (asynchronous) digital subscriber line (DSL) unit, Firewire interface, USB interface, and the like. One or more communications protocols can be used, such as HTTP, TCP/IP, RTP/RTSP, IPX and/or UDP.

As illustrated in FIG. 5, the one or more processors 502, the machine-readable medium 504, the user interface input devices 512, the user interface output devices 514, and/or the network interface 516 can be communicatively coupled to one another using a bus subsystem 520. Although the bus subsystem 520 is shown schematically as a single bus, alternative embodiments of the bus subsystem may use multiple buses. For example, RAM-based main memory can communicate directly with file storage systems using Direct Memory Access (“DMA”) systems.

### CONCLUSION

The Detailed Description referred to accompanying figures to illustrate exemplary embodiments consistent with the disclosure. References in the disclosure to “an exemplary embodiment” indicates that the exemplary embodiment described can include a particular feature, structure, or characteristic, but every exemplary embodiment may not necessarily include the particular feature, structure, or characteristic. Moreover, such phrases are not necessarily referring to the same exemplary embodiment. Further, any feature, structure, or characteristic described in connection with an exemplary embodiment can be included, independently or in any combination, with features, structures, or characteristics of other exemplary embodiments whether or not explicitly described.

The Detailed Description is not meant to be limiting. Rather, the scope of the disclosure is defined only in accordance with the following claims and their equivalents. It is to be appreciated that the Detailed Description section, and not the Abstract section, is intended to be used to interpret the claims. The Abstract section can set forth one or more, but not all exemplary embodiments, of the disclosure, and thus, are not intended to limit the disclosure and the following claims and their equivalents in any way.

The exemplary embodiments described within the disclosure have been provided for illustrative purposes and are not intended to be limiting. Other exemplary embodiments are possible, and modifications can be made to the exemplary embodiments while remaining within the spirit and scope of the disclosure. The disclosure has been described with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

Embodiments of the disclosure can be implemented in hardware, firmware, software application, or any combination thereof. Embodiments of the disclosure can also be implemented as instructions stored on a machine-readable medium, which can be read and executed by one or more processors. A machine-readable medium can include any mechanism for storing or transmitting information in a form readable by a machine (e.g., a computing circuitry). For example, a machine-readable medium can include non-transitory machine-readable mediums such as read only memory (ROM); random access memory (RAM); magnetic disk storage media; optical storage media; flash memory devices; and others. As another example, the machine-readable medium can include transitory machine-readable medium such as electrical, optical, acoustical, or other forms of propagated signals (e.g., carrier waves, infrared signals, digital signals, etc.). Further, firmware, software application, routines, instructions can be described herein as performing certain actions. However, it should be appreciated that such descriptions are merely for convenience and that such actions in fact result from computing devices, processors, controllers, or other devices executing the firmware, software application, routines, instructions, etc.

The Detailed Description of the exemplary embodiments fully revealed the general nature of the disclosure that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

What is claimed is:

1. A computing device for managing flow of information within a venue data processing environment, the computing device comprising:
a memory configured to store instructions; and
a processor configured to execute the instructions, the instructions, when executed by the processor, configuring the processor to:
execute a first software tool from among a plurality of software tools to generate a venue configuration file that specifies one or more characteristics, parameters, or attributes of a venue within the venue data processing environment, and
execute one or more second software tools from among the plurality of software tools to process pipeline input data in accordance with one or more corresponding characteristics, parameters, or attributes of the venue stored from among the venue configuration file to provide pipeline output data,
wherein each software tool from among the one or more second software tools, when executed by the processor, further configures the processor to:
load the venue configuration file; and
read the one or more corresponding characteristics, parameters, or attributes that are stored in the venue configuration file.

2. The computing device of claim 1, wherein the one or more characteristics, parameters, or attributes of the venue that are stored in the venue configuration file are organized within the venue configuration file in accordance with a common format or a common schema that is readable by the one or more second software tools without further modification.

3. The computing device of claim 1, wherein the pipeline input data and the pipeline output data comprise audio that is associated with an event being hosted by the venue.

4. The computing device of claim 3, wherein the one or more second software tools comprise a plurality of audio processing tools, the plurality of audio processing tools, when executed by the processor, configuring the processor to integrate, migrate, transform, monitor, visualize, or analyze the audio.

5. The computing device of claim 1, wherein the first software tool, when executed by the processor, further configures the processor to:
access venue data having the one or more characteristics, parameters, or attributes of the venue, the venue data being in a non-standard format or not-standard schema that is not readable by each software tool from among the one or more second software tools; and
compile the venue data to generate the venue configuration file having a common format or a common schema that is readable by each software tool from among the one or more second software tools.

6. The computing device of claim 5, wherein the venue data comprises venue dimensions and layout, acoustic characteristics, seating layout, stage dimensions and position, loudspeaker locations, microphone placement zones, power outlets and distribution, sound system specifications, cable routes and trays, audience areas, loading and access points, or environmental noise sources.

7. The computing device of claim 5, wherein the venue data comprises venue dimensions and layout, seating layout, stage dimensions and position, lightning grid, screen and projector locations, camera placement zones, power outlets and distribution, control room setup, cable routes and trays, backdrop and set design, access and exits, ambient light sources, existing audio-visual equipment, or network connectivity.

8. A method for managing flow of information within a venue data processing environment, the method comprising:
generating, by a first software tool from among a plurality of software tools executing a computing device, a venue configuration file that specifies one or more characteristics, parameters, or attributes of a venue within the venue data processing environment; and
processing, by one or more second software tools from among the plurality of software tools executing on the computing device, pipeline input data in accordance with one or more corresponding characteristics, parameters, or attributes of the venue stored from among the venue configuration file to provide pipeline output data, the processing comprising:
loading, by each software tool from among the one or more second software tools, the venue configuration file; and
reading, by each software tool from among the one or more second software tools, the one or more corresponding characteristics, parameters, or attributes that are stored in the venue configuration file.

9. The method of claim 8, wherein the one or more characteristics, parameters, or attributes of the venue that are stored in the venue configuration file are organized within the venue configuration file in accordance with a common format or a common schema that is readable by the one or more second software tools without further modification.

10. The method of claim 8, wherein the pipeline input data and the pipeline output data comprise audio that is associated with an event being hosted by the venue.

11. The method of claim 10, wherein the one or more second software tools comprise a plurality of audio processing tools, and
wherein the processing comprises integrating, migrating, transforming, monitoring, visualizing, or analyzing the audio.

12. The method of claim 8, wherein the generating comprises:
accessing, by the first software tool executing on the computing device, venue data having the one or more characteristics, parameters, or attributes of the venue, the venue data being in a non-standard format or not-standard schema that is not readable by each software tool from among the plurality of software tools; and
compiling, by the first software tool executing on the computing device, the venue data to generate the venue configuration file having a common format or a common schema that is readable by each software tool from among the plurality of software tools.

13. The method of claim 12, wherein the venue data comprises venue dimensions and layout, acoustic characteristics, seating layout, stage dimensions and position, loudspeaker locations, microphone placement zones, power outlets and distribution, sound system specifications, cable routes and trays, audience areas, loading and access points, or environmental noise sources.

14. The method of claim 12, wherein the venue data comprises venue dimensions and layout, seating layout, stage dimensions and position, lightning grid, screen and projector locations, camera placement zones, power outlets and distribution, control room setup, cable routes and trays, backdrop and set design, access and exits, ambient light sources, existing audio-visual equipment, or network connectivity.

15. A system for managing flow of information within a venue data processing environment, the system comprising:
a venue; and
a data pipeline architecture having a computing device, the computing device being configured to:
generate, by a first software tool from among a plurality of software tools executing on the computing device, a venue configuration file that specifies one or more characteristics, parameters, or attributes of a venue within the venue data processing environment, and
process, by one or more second software tools from among the plurality of software tools executing on the computing device, pipeline input data in accordance with one or more corresponding characteristics, parameters, or attributes of the venue stored from among the venue configuration file to provide pipeline output data,
wherein each software tool from among the one or more second software tools, when executed by the computing device, further configures the computing device to:
load the venue configuration file; and
read the one or more corresponding characteristics, parameters, or attributes that are stored in the venue configuration file.

16. The system of claim 15, wherein the one or more characteristics, parameters, or attributes of the venue that are stored in the venue configuration file are organized within the venue configuration file in accordance with a common format or a common schema that is readable by the one or more second software tools without further modification.

17. The system of claim 15, wherein the pipeline input data and the pipeline output data comprise audio that is associated with an event being hosted by the venue.

18. The system of claim 17, wherein the one or more second software tools comprise a plurality of audio processing tools, the plurality of audio processing tools, when executed by the computing device, configuring the computing device to integrate, migrate, transform, monitor, visualize, or analyze the audio.

19. The system of claim 15, wherein the first software tool, when executed by the computing device, further configures the computing device to:
access venue data having the one or more characteristics, parameters, or attributes of the venue, the venue data being in a non-standard format or not-standard schema that not readable by each software tool from among the plurality of software tools; and
compile the venue data to generate the venue configuration file having a common format or a common schema that is readable by each software tool from among the plurality of software tools.

20. The system of claim 19, wherein the venue data comprises venue dimensions and layout, acoustic characteristics, seating layout, stage dimensions and position, loudspeaker locations, microphone placement zones, power outlets and distribution, sound system specifications, cable routes and trays, audience areas, loading and access points, or environmental noise sources.
